(19) United States
(12) Patent Application Publication
(10) Pub. No.: US 2012/0075737 A1
(43) Pub. Date: Mar. 29, 2012

(54) METHOD OF MANUFACTURING COLOR FILTER AND COLOR FILTER

(75) Inventors: Junpei Ohkawara, Osaka-shi (JP); Hideto Kohketsu, Osaka-shi (JP)

(73) Assignee: SHARP KABUSHIKI KAISHA, Osaka-shi (JP)

(21) Appl. No.: 13/377,104

(22) PCT Filed: Apr. 13, 2010
(86) PCT No.: PCT/JP2010/056575

§ 371 Date: Dec. 8, 2011

(30) Foreign Application Priority Data
Jun. 9, 2009 (JP) 2009-138422

(51) Int. Cl. G02B 5/22; G03F 7/20

(52) U.S. Cl. 359/891; 430/7

(57) ABSTRACT

A method of manufacturing a color filter according to the present invention is a method of manufacturing a color filter including a plurality of translucent colored layers of different colors on a transparent substrate, including the steps of forming a black matrix layer on the transparent substrate with photolithography, forming one translucent colored layer selected from among the plurality of translucent colored layers with photolithography, and forming a remaining translucent colored layer of the plurality of translucent colored layers with ink-jetting. With this approach, a method of manufacturing a color filter that can attain excellent image quality and can be manufactured at low cost can be provided.

### REFERENCE TO RELATED APPLICATIONS

This application is a national stage application under 35 USC 371 of International Application No. PCT/JP2010/056575, filed Apr. 13, 2010, which claims the priority of Japanese Patent Application No. 2009-138422, filed Jun. 9, 2009, the contents of both of which prior applications are incorporated herein by reference.

### FIELD OF THE INVENTION

The present invention relates to a method of manufacturing a color filter included in a display panel of a liquid crystal display device and the like, and the color filter.

### BACKGROUND OF THE INVENTION

In general, a display panel of a liquid crystal display device, typified by a display of a liquid crystal television, a personal computer or the like, includes a color filter. The color filter is to display the display panel in color, and includes a translucent base member, and a plurality of groups of translucent colored layers of different colors provided on the base member. The groups of translucent colored layers typically include three groups of colored layers of red, green and blue, with each pixel including three colored layers of red, green and blue.

Typically, on the base member of the color filter, a light-blocking layer referred to as a black matrix layer is formed in addition to the above-mentioned colored layers. This black matrix layer is provided on border portions between the above-mentioned respective colored layers, and is formed in a lattice pattern by having a plurality of groups of openings. In these plurality of groups of openings of the black matrix layer formed in a lattice pattern, the above-mentioned plurality of groups of colored layers are provided in a corresponding manner.

The above-mentioned black matrix layer is to prevent light incidence on a clearance between the pixels or on a region where a TFT (Thin Film Transistor) has been formed. In general, it is known that light transmission through a clearance between pixels results in reduced image quality in a black display state to lower the contrast of a displayed image, and it is known that light incidence on a TFT causes generation of a leak current resulting from photoexcitation in a channel region of the TFT to reduce image quality. The above-mentioned black matrix layer is provided on the base member in order to prevent such phenomena, and blocks light to prevent the reduction in image quality described above.

These groups of translucent colored layers and the black matrix layer as a light-blocking layer can be formed with various types of thin film formation techniques, mainly photolithography and ink-jetting. With photolithography, a formation position and a shape of a thin film can be controlled with a high degree of accuracy, but increase in size and complexity of manufacturing equipment results, and a photolithography step needs to be repeated multiple times in order to form a plurality of different types of layers. Ink-jetting, on the other hand, is not suitable for controlling a formation position and a shape of a thin film with a high degree of accuracy, but only requires small and simple manufacturing equipment, and can form a plurality of different types of layers at a time.

When manufacturing a color filter, therefore, it is common to employ photolithography to form a black matrix layer that requires a high degree of accuracy in its formation position and shape, and employ ink-jetting to form a plurality of groups of translucent colored layers of different colors (see Japanese Patent Laying-Open No. 10-268803 (PTL 1), WO 01/007941 (PTL 2), and Japanese Patent Laying-Open No. 2006-243171 (PTL 3), for example). With this approach, a black matrix layer in a lattice pattern formed in advance with a high degree of accuracy with photolithography can be utilized as a partition when forming colored layers, and a plurality of groups of translucent colored layers of different colors can be formed at a time with a high degree of accuracy with ink-jetting. Accordingly, by forming a black matrix layer with photolithography, and then simultaneously forming groups of translucent colored layers of different colors at a time with ink-jetting as described above, a color filter can be manufactured simply with a high degree of accuracy by utilizing the respective advantages of photolithography and ink-jetting.

Japanese Patent Laying-Open No. 2007-108610 (PTL 4) discloses a method of manufacturing a particular color filter. The method of manufacturing a color filter disclosed in Japanese Patent Laying-Open No. 2007-108610 is a method of manufacturing a color filter included in a liquid crystal display device referred to as a color filter on array type (COA type), in which a group of blue colored layers and a partition layer substituted for the above-mentioned black matrix layer are simultaneously formed with photolithography (namely, the blue colored layers are substituted for the black matrix layer), and then a group of red colored layers and a group of green colored layers are formed with ink-jetting. With this approach, the manufacturing process can be simplified, thereby manufacturing the color filter at low cost.

### CITATION LIST

### Patent Literature

PTL 1: Japanese Patent Laying-Open No. 10-268803
PTL 2: WO 01/007941
PTL 3: Japanese Patent Laying-Open No. 2006-243171
PTL 4: Japanese Patent Laying-Open No. 2007-108610

### SUMMARY OF INVENTION

### Technical Problem

If a group of translucent colored layers is formed with ink-jetting, preparation of ink to drop is very important. In particular, it is necessary to optimize surface tension and viscosity of the ink, a pigment content, a dispersion state of the pigment in a solution and the like. If these conditions are not satisfied, a nozzle of an ink jet device will be clogged, dropped ink will be scattered to cause color mixture, or there will be a shortage of pigment, resulting in an insufficient color tone of a group of formed colored layers.

While development of red ink which will be the group of red colored layers, green ink which will be the group of green colored layers, and blue ink which will be the group of blue colored layers described above has advanced in recent years and preparation techniques satisfying the above conditions have been established, it is known that blue ink in particular is difficult to prepare compared to red ink and green ink.

Further, in order to realize image display with richer color tones, it has recently been studied to include, in addition to the above-mentioned three groups of colored layers of red, green and blue, groups of colored layers of other colors (e.g., a group of yellow colored layers, a group of magenta colored layers, a group of cyan colored layers, a group of white colored layers) in a color filter. For inks which will be the groups of colored layers of these other colors (e.g., yellow ink, magenta ink, cyan ink, white ink), however, it cannot be said that preparation techniques thereof have been well established.

For this reason, if all groups of translucent colored layers are formed only with ink-jetting, an increase in manufacturing costs results due to preparation of the inks described above. In order to manufacture a color filter capable of realizing high-quality image display, therefore, some improvement still needs to be made.

Now, focusing on manufacturing a color filter including only three groups of colored layers of red, green and blue at low cost, a group of blue colored layers and a partition layer substituted for a black matrix layer may be simultaneously formed with photolithography to eliminate the need for preparing blue ink, as disclosed in Japanese Patent Laying-Open No. 2007-108610 described above. When such method of manufacturing a color filter is employed, however, light cannot be sufficiently blocked in the partition layer substituted for a black matrix layer, inevitably resulting in reduced image quality.

In general, a spacer layer is provided on a predetermined portion of the light-blocking layer of the color filter described above. This spacer layer is to form a gap for sealing liquid crystal between a CF (Color Filter) substrate on which the color filter is formed and a TFT substrate arranged opposite to the CF substrate, and is also formed on the black matrix layer with either photolithography or ink-jetting. This spacer layer is typically formed in a different step from those for forming the black matrix layer and the groups of translucent colored layers described above, which also contributes to an increased cost of manufacturing the color filter.

Thus, the present invention was made in view of the circumstances described above, and an object of the present invention is to provide a color filter that can attain excellent image quality and can be manufactured at low cost, and a method of manufacturing the same.

### Solution to Problem

A method of manufacturing a color filter according to the present invention is a method of manufacturing a color filter including a plurality of groups of translucent colored layers of different colors on a translucent base member, and includes the following steps.

(a) Forming a light-blocking layer including a plurality of groups of openings on the base member with photolithography.

(b) Forming one group of translucent colored layers selected from among the plurality of groups of translucent colored layers in one group of openings selected from among the plurality of groups of openings with photolithography.

(c) Forming another group of translucent colored layers selected from among the plurality of groups of translucent colored layers in another group of openings selected from among the plurality of groups of openings with ink-jetting.

In the method of manufacturing a color filter according to the present invention, the step (b) of forming the one group of translucent colored layers with photolithography may be performed before the step (c) of forming the another group of translucent colored layers with ink-jetting, or the step (c) of forming the another group of translucent colored layers with ink-jetting may be performed before the step (b) of forming the one group of translucent colored layers with photolithography.

In the method of manufacturing a color filter according to the present invention, in the step (b) of forming the one group of translucent colored layers with photolithography, a group of spacer layers positioned to project on a predetermined portion of the light-blocking layer may be formed simultaneously with the one group of translucent colored layers.

In the method of manufacturing a color filter according to the present invention, if the plurality of groups of translucent colored layers include at least four or more groups of translucent colored layers of different colors, it is preferable that three groups of translucent colored layers selected from among these four or more groups of translucent colored layers be formed with ink-jetting, and a remaining group of translucent colored layers be formed with photolithography.

In the method of manufacturing a color filter according to the present invention, if the plurality of groups of translucent colored layers consist of three groups of translucent colored layers composed of a group of red translucent colored layers, a group of green translucent colored layers and a group of blue translucent colored layers, it is preferable that at least one group of translucent colored layers selected from among these three groups of translucent colored layers be formed with photolithography, and a remaining group of translucent colored layers be formed with ink-jetting.

In the method of manufacturing a color filter according to the present invention, if the plurality of groups of translucent colored layers consist of four groups of translucent colored layers composed of a group of red translucent colored layers, a group of green translucent colored layers, a group of blue translucent colored layers and a group of yellow translucent colored layers, it is preferable that at least one group of translucent colored layers selected from among these four groups of translucent colored layers be formed with photolithography, and a remaining group of translucent colored layers be formed with ink-jetting.

In the method of manufacturing a color filter according to the present invention, if the plurality of groups of translucent colored layers consist of four groups of translucent colored layers composed of a group of red translucent colored layers, a group of green translucent colored layers, a group of blue translucent colored layers and a group of white translucent colored layers, it is preferable that at least one group of translucent colored layers selected from among these four groups of translucent colored layers be formed with photolithography, and a remaining group of translucent colored layers be formed with ink-jetting.

In the method of manufacturing a color filter according to the present invention, if the plurality of groups of translucent colored layers consist of six groups of translucent colored layers composed of a group of red translucent colored layers, a group of green translucent colored layers, a group of blue translucent colored layers, a group of yellow translucent colored layers, a group of magenta translucent colored layers and a group of cyan translucent colored layers, it is preferable that at least one group of translucent colored layers selected from among these six groups of translucent colored layers be formed with photolithography, and a remaining group of translucent colored layers be formed with ink-jetting.

In the method of manufacturing a color filter according to the present invention, it is preferable that the light-blocking layer be a black matrix layer formed of a low-reflection metallic film or a synthetic resin film.

A color filter according to the present invention includes a translucent base member, a light-blocking layer including a plurality of groups of openings provided on the base member, and a plurality of groups of translucent colored layers of different colors provided on the base member. One group of translucent colored layers selected from among the plurality of groups of translucent colored layers is formed in one group of openings selected from among the plurality of groups of openings with photolithography. Another group of translucent colored layers selected from among the plurality of groups of translucent colored layers is formed in another group of openings selected from among the plurality of groups of openings with ink-jetting.

The color filter according to the present invention may further include a group of spacer layers positioned to project on a predetermined portion of the light-blocking layer. In that case, it is preferable that the one group of translucent colored layers and the group of spacer layers be simultaneously formed in one step.

In the color filter according to the present invention, the plurality of groups of translucent colored layers may consist of three groups of translucent colored layers composed of a group of red translucent colored layers, a group of green translucent colored layers and a group of blue translucent colored layers.

In the color filter according to the present invention, the plurality of groups of translucent colored layers may consist of four groups of translucent colored layers composed of a group of red translucent colored layers, a group of green translucent colored layers, a group of blue translucent colored layers and a group of yellow translucent colored layers.

In the color filter according to the present invention, the plurality of groups of translucent colored layers may consist of four groups of translucent colored layers composed of a group of red translucent colored layers, a group of green translucent colored layers, a group of blue translucent colored layers and a group of white translucent colored layers.

In the color filter according to the present invention, the plurality of groups of translucent colored layers may consist of six groups of translucent colored layers composed of a group of red translucent colored layers, a group of green translucent colored layers, a group of blue translucent colored layers, a group of yellow translucent colored layers, a group of magenta translucent colored layers and a group of cyan translucent colored layers.

In the color filter according to the present invention, it is preferable that the light-blocking layer be a black matrix layer formed of a low-reflection metallic film or a synthetic resin film.

### ADVANTAGEOUS EFFECTS OF INVENTION

According to the present invention, a color filter that can attain excellent image quality and can be manufactured at low cost, and a method of manufacturing the same can be provided.

### BRIEF DESCRIPTION OF DRAWINGS

FIG. 1 is a schematic cross-sectional view of a liquid crystal panel including a color filter in a first embodiment of the present invention.

FIG. 2 is a plan view of an enlarged portion of the color filter in the first embodiment of the present invention.

FIG. 3 is a flow diagram for explaining a method of manufacturing the color filter in the first embodiment of the present invention.

FIG. 4A is a schematic cross-sectional view for explaining the method of manufacturing the color filter in the first embodiment of the present invention.

FIG. 4B is a schematic cross-sectional view for explaining the method of manufacturing the color filter in the first embodiment of the present invention.

FIG. 4C is a schematic cross-sectional view for explaining the method of manufacturing the color filter in the first embodiment of the present invention.

FIG. 4D is a schematic cross-sectional view for explaining the method of manufacturing the color filter in the first embodiment of the present invention.

FIG. 5A is a schematic cross-sectional view for explaining the method of manufacturing the color filter in the first embodiment of the present invention.

FIG. 5B is a schematic cross-sectional view for explaining the method of manufacturing the color filter in the first embodiment of the present invention.

FIG. 5C is a schematic cross-sectional view for explaining the method of manufacturing the color filter in the first embodiment of the present invention.

FIG. 5D is a schematic cross-sectional view for explaining the method of manufacturing the color filter in the first embodiment of the present invention.

FIG. 6 is a schematic cross-sectional view for explaining the method of manufacturing the color filter in the first embodiment of the present invention.

FIG. 7 is a schematic cross-sectional view of a liquid crystal panel including a color filter in a second embodiment of the present invention.

FIG. 8 is a plan view of an enlarged portion of the color filter in the second embodiment of the present invention.

FIG. 9 is a flow diagram for explaining a method of manufacturing the color filter in the second embodiment of the present invention.

FIG. 10A is a schematic cross-sectional view for explaining the method of manufacturing the color filter in the second embodiment of the present invention.

FIG. 10B is a schematic cross-sectional view for explaining the method of manufacturing the color filter in the second embodiment of the present invention.

FIG. 10C is a schematic cross-sectional view for explaining the method of manufacturing the color filter in the second embodiment of the present invention.

FIG. 10D is a schematic cross-sectional view for explaining the method of manufacturing the color filter in the second embodiment of the present invention.

FIG. 11A is a schematic cross-sectional view for explaining the method of manufacturing the color filter in the second embodiment of the present invention.

FIG. 11B is a schematic cross-sectional view for explaining the method of manufacturing the color filter in the second embodiment of the present invention.

FIG. 11C is a schematic cross-sectional view for explaining the method of manufacturing the color filter in the second embodiment of the present invention.

FIG. 11D is a schematic cross-sectional view for explaining the method of manufacturing the color filter in the second embodiment of the present invention.

FIG. 12 is a schematic cross-sectional view for explaining the method of manufacturing the color filter in the second embodiment of the present invention.

FIG. 13 is a plan view of an enlarged portion of a color filter according to another example in the second embodiment of the present invention.

FIG. 14 is a schematic cross-sectional view of a liquid crystal panel including a color filter in a third embodiment of the present invention.

FIG. 15 is a plan view of an enlarged portion of the color filter in the third embodiment of the present invention.

FIG. 16 is a flow diagram for explaining a method of manufacturing the color filter in the third embodiment of the present invention.

FIG. 17A is a schematic cross-sectional view for explaining the method of manufacturing the color filter in the third embodiment of the present invention.

FIG. 17B is a schematic cross-sectional view for explaining the method of manufacturing the color filter in the third embodiment of the present invention.

FIG. 18A is a schematic cross-sectional view for explaining the method of manufacturing the color filter in the third embodiment of the present invention.

FIG. 18B is a schematic cross-sectional view for explaining the method of manufacturing the color filter in the third embodiment of the present invention.

FIG. 19A is a schematic cross-sectional view for explaining the method of manufacturing the color filter in the third embodiment of the present invention.

FIG. 19B is a schematic cross-sectional view for explaining the method of manufacturing the color filter in the third embodiment of the present invention.

FIG. 20A is a schematic cross-sectional view for explaining the method of manufacturing the color filter in the third embodiment of the present invention.

FIG. 20B is a schematic cross-sectional view for explaining the method of manufacturing the color filter in the third embodiment of the present invention.

FIG. 21A is a schematic cross-sectional view for explaining the method of manufacturing the color filter in the third embodiment of the present invention.

FIG. 21B is a schematic cross-sectional view for explaining the method of manufacturing the color filter in the third embodiment of the present invention.

FIG. 22 is a schematic cross-sectional view for explaining the method of manufacturing the color filter in the third embodiment of the present invention.

### DETAILED DESCRIPTION OF THE INVENTION

Embodiments of the present invention will be described hereinafter in detail with reference to the drawings. A liquid crystal panel including a color filter in each of the following first to third embodiments is a so-called active matrix type liquid crystal panel, in which a plurality of pixels arranged in a matrix are individually controlled by TFTs provided on the pixels. A pixel as referred to herein corresponds to one pixel forming one unit of display, and includes a plurality of colored layers of different colors. Thus, a plurality of TFTs as described above are provided in one pixel correspondingly to a plurality of colored layers included in one pixel.

### First Embodiment

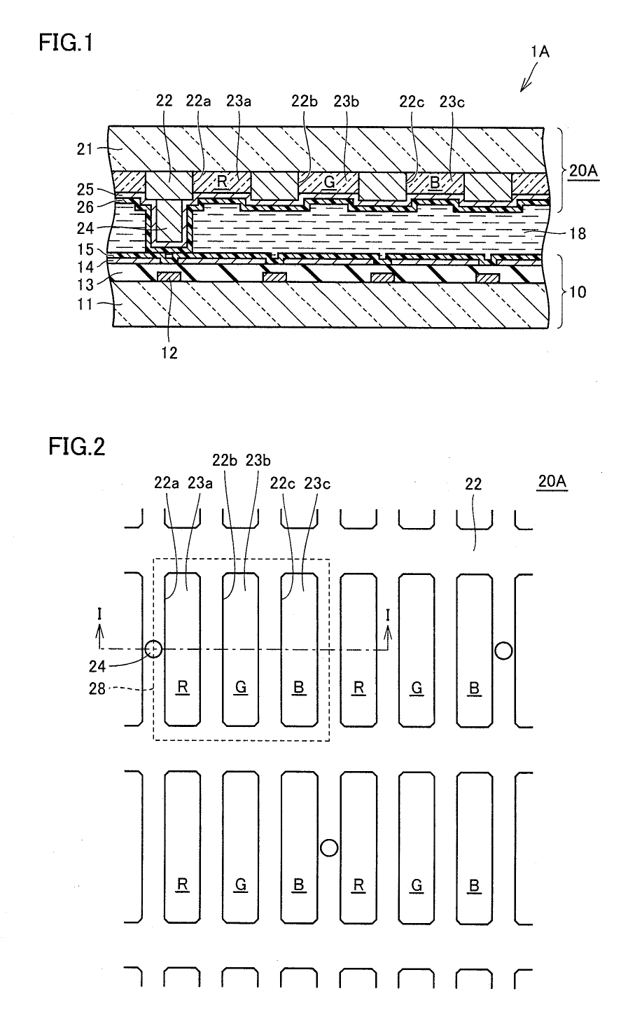

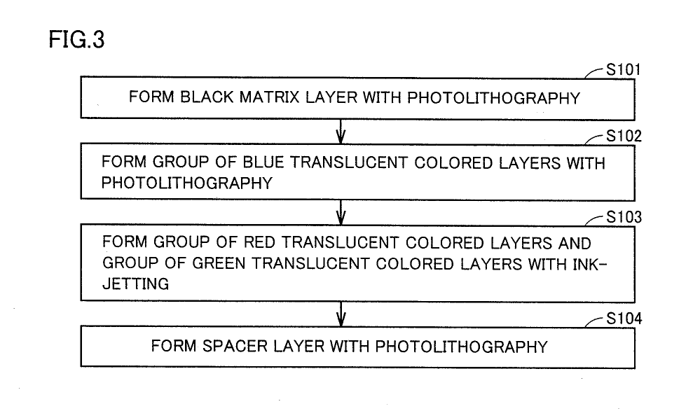

FIG. 1 is a schematic cross-sectional view of a liquid crystal panel including a color filter in a first embodiment of the present invention, and FIG. 2 is a plan view of an enlarged portion of the color filter shown in FIG. 1. FIG. 1 is a schematic cross-sectional view showing the liquid crystal panel cut along the line I-I shown in FIG. 2. First, referring to FIGS. 1 and 2, the color filter and a structure of the liquid crystal panel including the color filter in the present embodiment will be described in detail.

As shown in FIG. 2, the color filter in the present embodiment includes stripe-shaped colored layers of three colors composed of a red colored layer 23a, a green colored layer 23b and a blue colored layer 23c in parallel with one another in each pixel 28. Thus, the color filter in the present embodiment includes three groups of translucent colored layers composed of a group of red translucent colored layers, a group of green translucent colored layers and a group of blue translucent colored layers.

As shown in FIGS. 1 and 2, a liquid crystal panel 1A including the color filter in the present embodiment mainly includes a TFT substrate 10, a CF substrate 20A, and liquid crystal 18 sealed between TFT substrate 10 and CF substrate 20A.

TFT substrate 10 is also referred to as an active matrix substrate, and mainly includes a transparent substrate 11, a TFT circuit layer 12, an insulating layer 13, a pixel electrode 14, and a liquid-crystal alignment film 15.

Transparent substrate 11 has translucent characteristics, and is formed of a plate-like glass substrate or plastic substrate, for example. TFT circuit layer 12 is provided on a main surface of transparent substrate 11 correspondingly to colored layers 23a, 23b, 23c included in each pixel 28, and includes a circuit having a TFT, wiring and the like. The TFT is made of amorphous silicon or polysilicon, for example, and the wiring is made of aluminum (Al), copper (Cu), tantalum (Ta), titanium (Ti) or an alloy thereof, for example. Insulating layer 13 is provided on the main surface of transparent substrate 11 to cover TFT circuit layer 12, and is made of a silicon compound such as silicon nitride (SiNx) or silicon oxide (SiOx), or a resin material such as polyimide resin or acrylic resin.

Pixel electrode 14 is provided on insulating layer 13 correspondingly to colored layers 23a, 23b, 23c included in each pixel 28, and is electrically connected to TFT circuit layer 12 described above. Pixel electrode 14 is formed of a transparent electrode film such as an ITO (Indium Thin Oxide) film (namely, a mixed film of indium oxide (In₂O₃) and tin oxide (SnO₂)). Liquid-crystal alignment film 15 is provided on insulating layer 13 to cover pixel electrode 14, and is made of a resin material such as polyimide resin.

CF substrate 20A is also referred to as a counter substrate, corresponds to a color filter, and mainly includes a transparent substrate 21, a black matrix layer 22, the three colored layers of different colors composed of red colored layer 23a, green colored layer 23b and blue colored layer 23c provided for each pixel, a spacer layer 24, a counter electrode 25, and a liquid-crystal alignment film 26.

Transparent substrate 21 corresponds to a translucent base member, and is formed of a plate-like glass substrate or plastic substrate, for example. Black matrix layer 22 corresponds to a light-blocking layer, and is provided on a main surface of transparent substrate 21. Three colored layers 23a, 23b, 23c of different colors are provided on the main surface of transparent substrate 21, in portions where black matrix layer 22 is not formed.

Black matrix layer 22 is provided on border portions between respective colored layers 23a, 23b, 23c, and is formed in a lattice pattern by having a plurality of groups of openings. Here, the plurality of groups of openings provided in black matrix layer 22 include three groups of openings composed of a first group of openings, a second group of openings and a third group of openings, which include a first opening 22a, a second opening 22b and a third opening 22c provided in each pixel 28, respectively, with the above-mentioned group of red translucent colored layers being provided in the first group of openings, the above-mentioned group of green translucent colored layers being provided in the second group of openings, and the above-mentioned group of blue translucent colored layers being provided in the third group of openings, respectively.

Black matrix layer 22 is formed with photolithography, and is formed of a low-reflection metallic film made of chromium (Cr), molybdenum (Mo) or the like, or a synthetic resin film made of black photosensitive resin containing carbon particles dispersed in photosensitive resin, for example. Red colored layer 23a is formed with ink-jetting using red ink, and is formed of a thermosetting resin film containing dispersed red pigment, for example. Green colored layer 23b is formed with ink-jetting using green ink, and is formed of a thermosetting resin film containing dispersed green pigment, for example. On the other hand, blue colored layer 23c is formed with photolithography, and is formed of a photosensitive resin film containing dispersed blue pigment, for example.

Spacer layer 24 is provided on a predetermined portion of black matrix layer 22.

Spacer layer 24 is to form a predetermined gap between TFT substrate 10 and CF substrate 20A, and a plurality of spacer layers 24 are provided on a surface of the color filter. Spacer layer 24 is formed with photolithography, and as with black matrix layer 22, is formed of a low-reflection metallic film made of chromium (Cr), molybdenum (Mo) or the like, or a synthetic resin film made of black photosensitive resin containing carbon particles dispersed in photosensitive resin, for example.

Counter electrode 25 is provided to cover black matrix layer 22, red colored layer 23a, green colored layer 23b, blue colored layer 23c and spacer layer 24 described above. Counter electrode 25 is formed of a transparent electrode film such as an ITO film. Liquid-crystal alignment film 26 is provided on counter electrode 25, and is made of a resin material such as polyimide resin.

Liquid crystal 18 is sealed between TFT substrate 10 and CF substrate 20A. Liquid crystal 18 has a characteristic of having a light transmittance varied with an applied voltage, and is disposed between pixel electrode 14 provided on TFT substrate 10 described above and counter electrode 25 provided on CF substrate 20A described above. A not-shown polarizing plate is attached to each main surface of TFT substrate 10 and CF substrate 20A not facing liquid crystal 18.

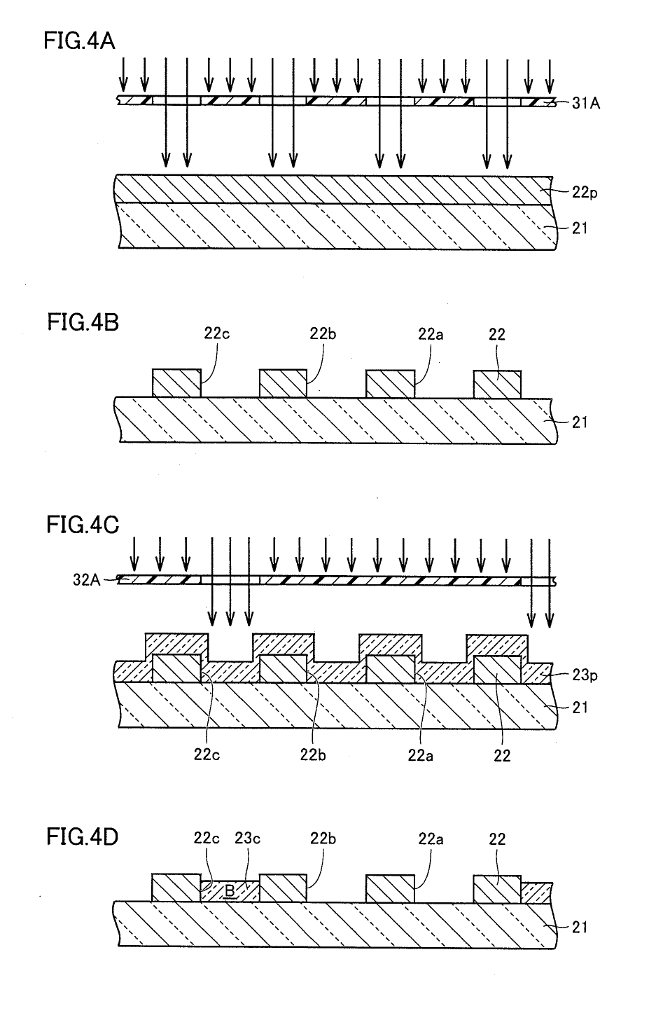

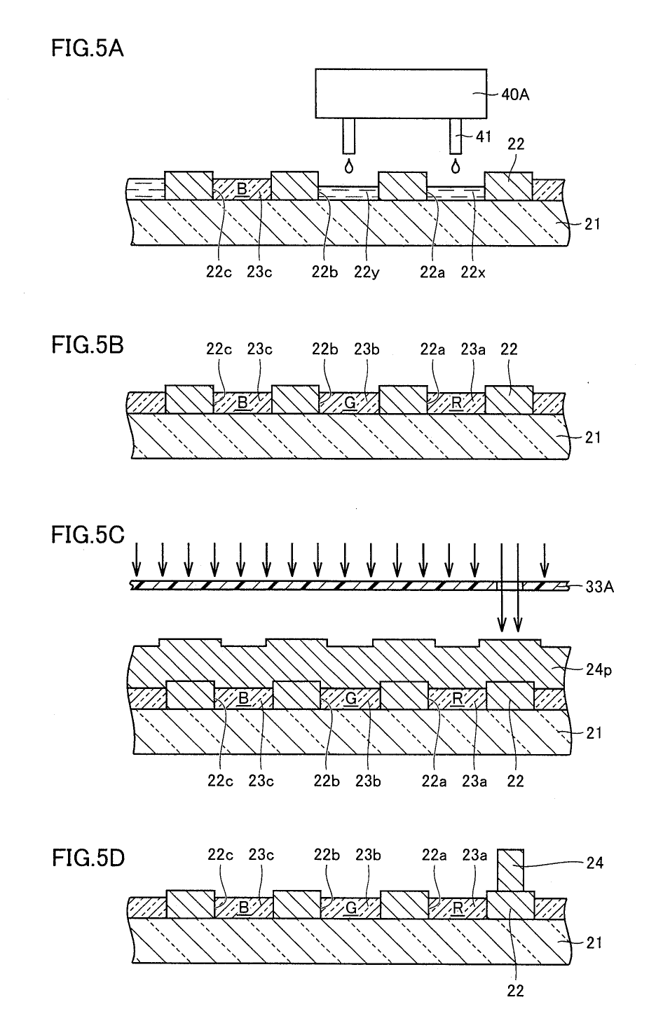

FIG. 3 is a flow diagram for explaining a method of manufacturing the color filter in the present embodiment, and FIGS. 4 to 6 are schematic cross-sectional views during a manufacturing process of manufacturing the color filter in the present embodiment in accordance with the flow. Referring now to FIGS. 3 to 6, the method of manufacturing the color filter in the present embodiment will be described in detail.

As shown in FIG. 3, when manufacturing the color filter in the present embodiment, transparent substrate 21 as a translucent base member is first prepared, and black matrix layer 22 as a light-blocking layer is formed on transparent substrate 21 with photolithography (step S101). More specifically, as shown in FIG. 4, black photosensitive resin liquid is applied with spin coating and dried, for example, on the main surface of transparent substrate 21, to form a black photosensitive resin layer 22p, and black photosensitive resin layer 22p is then exposed to light with a photomask 31A having a predetermined opening shape, followed by development with a predetermined etching solution. As a result, black matrix layer 22 having first opening 22a, second opening 22b and third opening 22c is formed on transparent substrate 21 as shown in FIG. 4B.

Next, as shown in FIG. 3, a group of blue translucent colored layers is formed on transparent substrate 21 with photolithography (step S102). More specifically, as shown in FIG. 4C, blue photosensitive resin liquid is applied with spin coating and dried, for example, across the main surface of transparent substrate 21 having black matrix layer 22 formed thereon, to form a blue photosensitive resin layer 23p, and blue photosensitive resin layer 23p is then exposed to light with a photomask 32A having a predetermined opening shape, followed by development with a predetermined etching solution. As a result, blue colored layer 23c is formed in third opening 22c of black matrix layer 22 as shown in FIG. 4D.

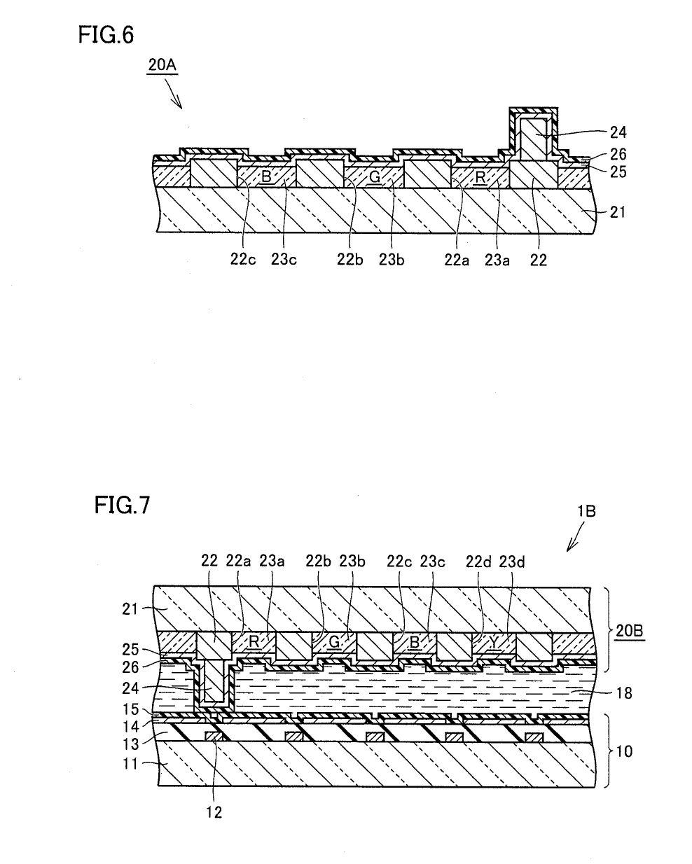

Next, as shown in FIG. 3, a group of red translucent colored layers and a group of green translucent colored layers are formed on transparent substrate 21 with ink-jetting (step S103). More specifically, as shown in FIG. 5A, a predetermined amount of red ink 23x is dropped onto a portion of transparent substrate 21 where first opening 22a of black matrix layer 22 has been provided, and a predetermined amount of green ink 23y is dropped onto a portion of transparent substrate 21 where second opening 22b of black matrix layer 22 has been provided, respectively, with a nozzle 41 provided on an ink jet head 40A, and then cured by heating. As a result, red colored layer 23a is formed in first opening 22a of black matrix layer 22, and green colored layer 23b is formed in second opening 22b of black matrix layer 22, respectively, as shown in FIG. 5B.

Next, as shown in FIG. 3, a group of spacer layers is formed on a predetermined portion of black matrix layer 22 with photolithography (step S104). More specifically, as shown in FIG. 5C, black photosensitive resin liquid is applied with spin coating and dried, for example, across black matrix layer 22, the group of red translucent colored layers, the group of green translucent colored layers and the group of blue translucent colored layers, to form a black photosensitive resin layer 24p, and black photosensitive resin layer 24p is then exposed to light with a photomask 33A having a predetermined opening shape, followed by development with a predetermined etching solution. As a result, spacer layer 24 is formed on the predetermined portion of black matrix layer 22 as shown in FIG. 5D.

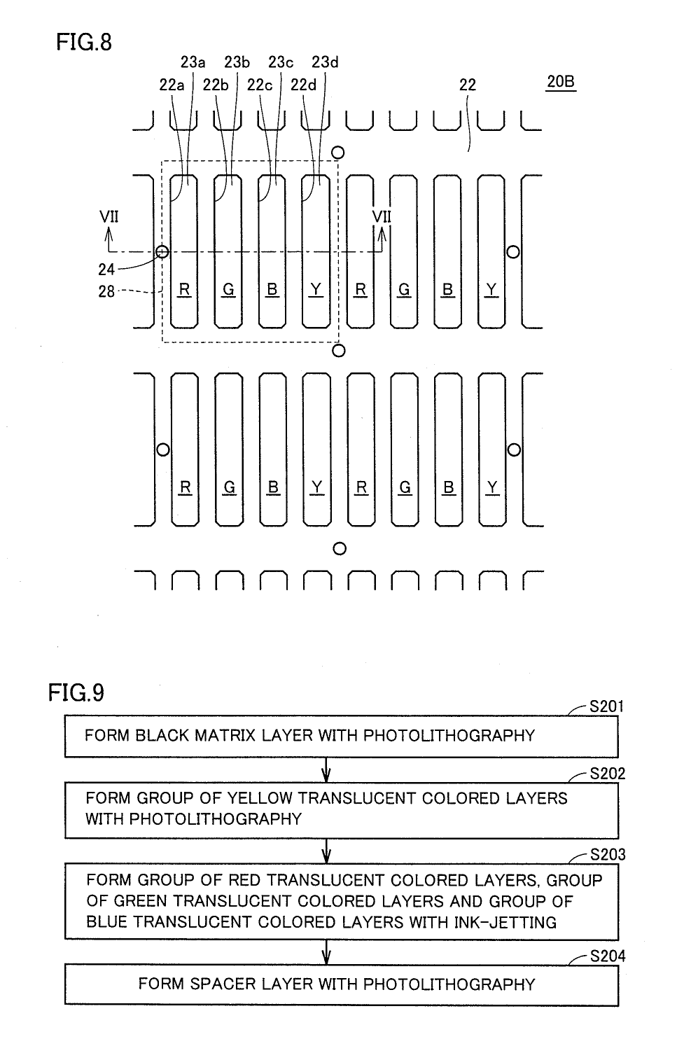

Next, an ITO film is formed with sputtering, for example, to cover black matrix layer 22, the group of red translucent colored layers, the group of green translucent colored layers, the group of blue translucent colored layers and the group of spacer layers, to form counter electrode 25, and polyimide resin is further applied with spin coating and dried on counter electrode 25, for example, to form liquid-crystal alignment film 26. As a result, manufacture of CF substrate 20A (color filter) as shown in FIG. 6 is completed.

As described above, in the present embodiment, the black matrix layer is formed with photolithography, the group of blue translucent colored layers is formed with photolithography, and the group of red translucent colored layers and the group of green translucent colored layers are formed with ink-jetting. Thus, the black matrix layer can be formed with a higher degree of accuracy with photolithography, and the group of blue translucent colored layers can be formed with photolithography rather than ink-jetting using blue ink which is difficult to prepare compared to inks of other colors, further facilitating the formation of the group of blue translucent colored layers. Moreover, the group of red translucent colored layers and the group of green translucent colored layers can be simultaneously formed with ink-jetting, further facilitating the formation of the group of red translucent colored layers and the group of green translucent colored layers. Accordingly, the color filter can be manufactured by further utilizing the respective advantages of photolithography and ink-jetting than ever before.

Furthermore, in the color filter of the present embodiment, the black matrix layer is formed on the border portions between the colored layers, so that the black matrix layer can prevent light incidence on a clearance between the pixels or on a region where a TFT has been formed. Accordingly, the liquid crystal panel including the color filter in the present embodiment is capable of high-quality display.

According to the present embodiment, therefore, a liquid crystal panel capable of high-quality display can be manufactured at low cost by utilizing the respective advantages of photolithography and ink-jetting, allowing manufacture of a high-performance liquid crystal panel at low cost.

### Second Embodiment

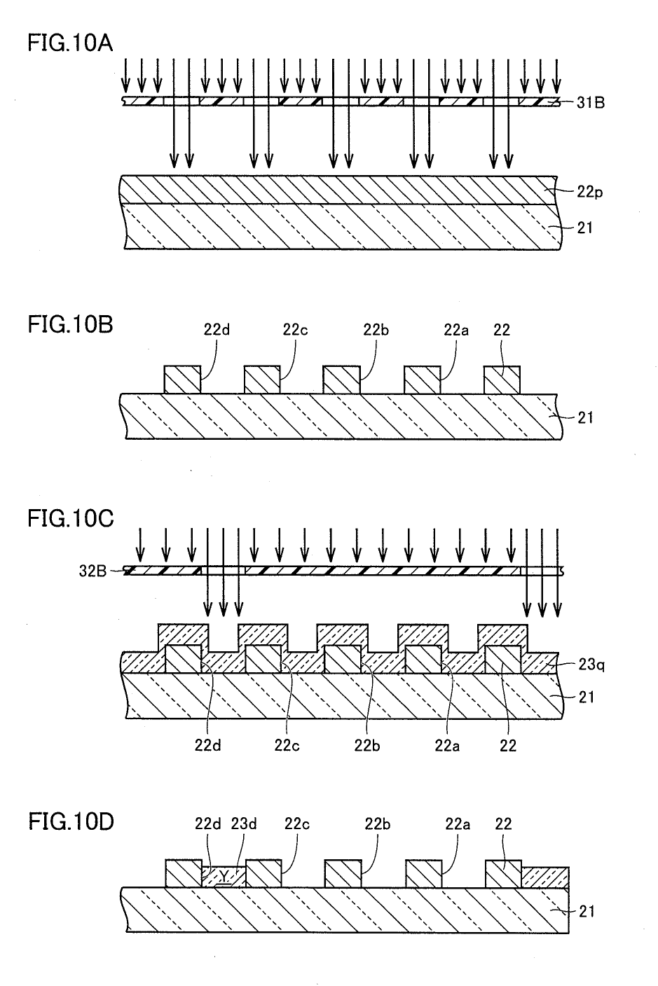

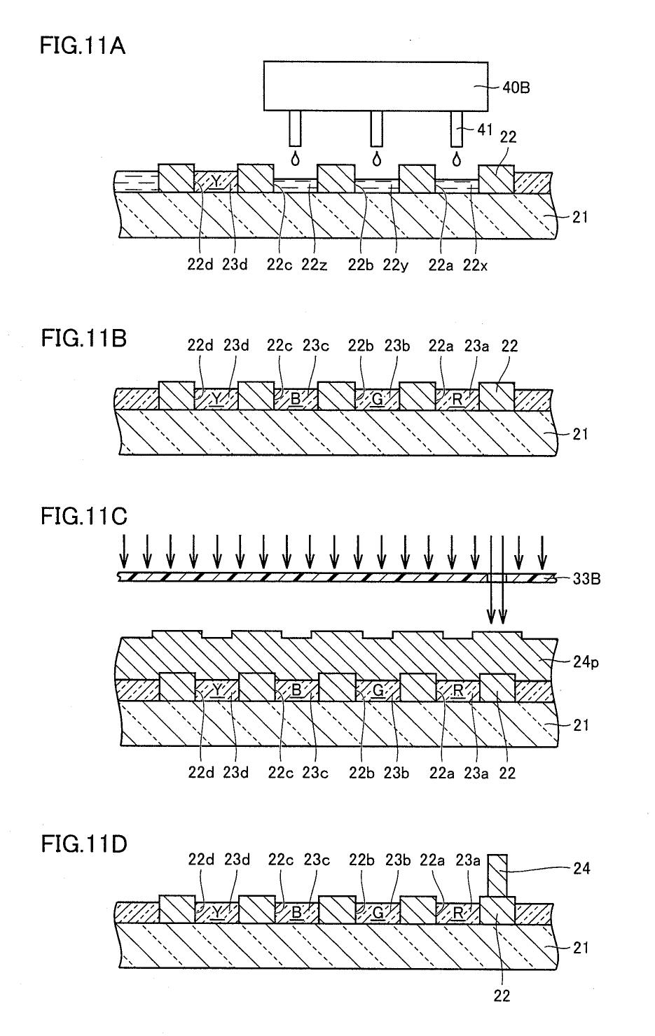

FIG. 7 is a schematic cross-sectional view of a liquid crystal panel including a color filter in a second embodiment of the present invention, and FIG. 8 is a plan view of an enlarged portion of the color filter shown in FIG. 7. FIG. 7 is a schematic cross-sectional view showing the liquid crystal panel cut along the line VII-VII shown in FIG. 8. First, referring to FIGS. 7 and 8, the color filter and a structure of the liquid crystal panel including the color filter in the present embodiment will be described in detail. It is noted that the same reference signs are used in the drawings to indicate similar parts to those in the first embodiment described above, and description thereof will not be repeated.

As shown in FIG. 8, the color filter in the present embodiment includes stripe-shaped colored layers of four colors composed of red colored layer 23a, green colored layer 23b, blue colored layer 23c and a yellow colored layer 23d in parallel with one another in each pixel 28. Thus, the color filter in the present embodiment includes four groups of translucent colored layers composed of a group of red translucent colored layers, a group of green translucent colored layers, a group of blue translucent colored layers, and a group of yellow translucent colored layers.

As shown in FIGS. 7 and 8, a liquid crystal panel 1B including the color filter in the present embodiment mainly includes TFT substrate 10, a CF substrate 20B, and liquid crystal 18 sealed between TFT substrate 10 and CF substrate 20B. Here, liquid crystal panel 1B including the color filter in the present embodiment is different from liquid crystal panel 1A in the above first embodiment only in structure of the CF substrate.

CF substrate 20B corresponds to a color filter, and mainly includes transparent substrate 21, black matrix layer 22, the four colored layers of different colors composed of red colored layer 23a, green colored layer 23b, blue colored layer 23c and yellow colored layer 23d provided for each pixel, spacer layer 24, counter electrode 25, and liquid-crystal alignment film 26.

Transparent substrate 21 corresponds to a translucent base member, and is formed of a plate-like glass substrate or plastic substrate, for example. Black matrix layer 22 corresponds to a light-blocking layer, and is provided on the main surface of transparent substrate 21. Four colored layers 23a, 23b, 23c, 23d of different colors are provided on the main surface of transparent substrate 21, in portions where black matrix layer 22 is not formed.

Black matrix layer 22 is provided on border portions between respective colored layers 23a, 23b, 23c, 23d, and is formed in a lattice pattern by having a plurality of groups of openings. Here, the plurality of groups of openings provided in black matrix layer 22 include four groups of openings composed of a first group of openings, a second group of openings, a third group of openings and a fourth group of openings, which include first opening 22a, second opening 22b, third opening 22c and a fourth opening 22d provided in each pixel 28, respectively, with the above-mentioned group of red translucent colored layers being provided in the first group of openings, the above-mentioned group of green translucent colored layers being provided in the second group of openings, the above-mentioned group of blue translucent colored layers being provided in the third group of openings, and the above-mentioned yellow colored layers being provided in the fourth group of openings, respectively.

Black matrix layer 22 is formed with photolithography, and is formed of a low-reflection metallic film made of chromium (Cr), molybdenum (Mo) or the like, or a synthetic resin film made of black photosensitive resin containing carbon particles dispersed in photosensitive resin, for example. Red colored layer 23a is formed with ink-jetting using red ink, and is formed of a thermosetting resin film containing dispersed red pigment, for example. Green colored layer 23b is formed with ink-jetting using green ink, and is formed of a thermosetting resin film containing dispersed green pigment, for example. Blue colored layer 23c is formed with ink-jetting using blue ink, and is formed of a thermosetting resin film containing dispersed blue pigment, for example. On the other hand, yellow colored layer 23d is formed with photolithography, and is formed of a photosensitive resin film containing dispersed yellow pigment, for example.

Spacer layer 24 is provided on a predetermined portion of black matrix layer 22. Spacer layer 24 is to form a predetermined gap between TFT substrate 10 and CF substrate 20B, and a plurality of spacer layers 24 are provided on the surface of the color filter. Spacer layer 24 is formed with photolithography, and as with black matrix layer 22, is formed of a low-reflection metallic film made of chromium (Cr), molybdenum (Mo) or the like, or a synthetic resin film made of black photosensitive resin containing carbon particles dispersed in photosensitive resin, for example.

Counter electrode 25 is provided to cover black matrix layer 22, red colored layer 23a, green colored layer 23b, blue colored layer 23c, yellow colored layer 23d and spacer layer 24 described above. Counter electrode 25 is formed of a transparent electrode film such as an ITO film. Liquid-crystal alignment film 26 is provided on counter electrode 25, and is made of a resin material such as polyimide resin.

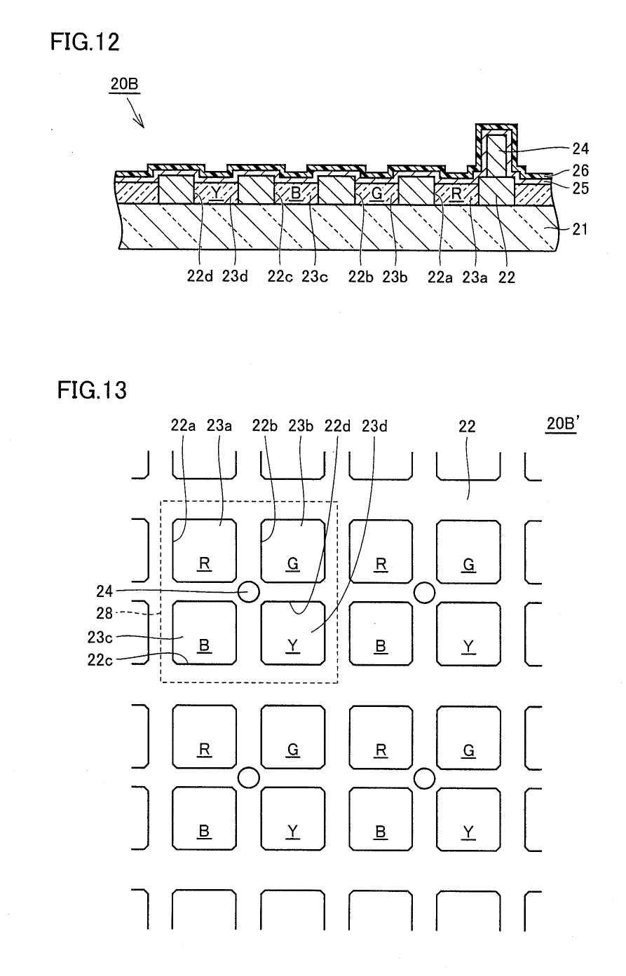

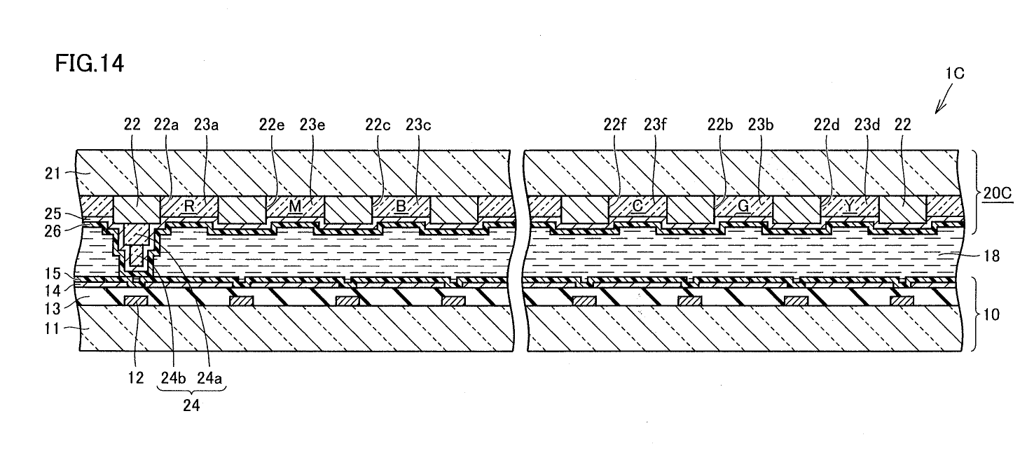

FIG. 9 is a flow diagram for explaining a method of manufacturing the color filter in the present embodiment, and FIGS. 10 to 12 are schematic cross-sectional views during a manufacturing process of manufacturing the color filter in the present embodiment in accordance with the flow. Referring now to FIGS. 9 to 12, the method of manufacturing the color filter in the present embodiment will be described in detail.

As shown in FIG. 9, when manufacturing the color filter in the present embodiment, transparent substrate 21 as a translucent base member is first prepared, and black matrix layer 22 as a light-blocking layer is formed on transparent substrate 21 with photolithography (step S201). More specifically, as shown in FIG. 10A, black photosensitive resin liquid is applied with spin coating and dried, for example, on the main surface of transparent substrate 21, to form black photosensitive resin layer 22p, and black photosensitive resin layer 22p is then exposed to light with a photomask 31B having a predetermined opening shape, followed by development with a predetermined etching solution. As a result, black matrix layer 22 having first opening 22a, second opening 22b, third opening 22c and fourth opening 22d is formed on transparent substrate 21 as shown in FIG. 10B.

Next, as shown in FIG. 9, a group of yellow translucent colored layers is formed on transparent substrate 21 with photolithography (step S202). More specifically, as shown in FIG. 10C, yellow photosensitive resin liquid is applied with spin coating and dried, for example, across the main surface of transparent substrate 21 having black matrix layer 22 formed thereon, to form a yellow photosensitive resin layer 23q, and yellow photosensitive resin layer 23q is then exposed to light with a photomask 32B having a predetermined opening shape, followed by development with a predetermined etching solution. As a result, yellow colored layer 23d is formed in fourth opening 22d of black matrix layer 22 as shown in FIG. 10D.

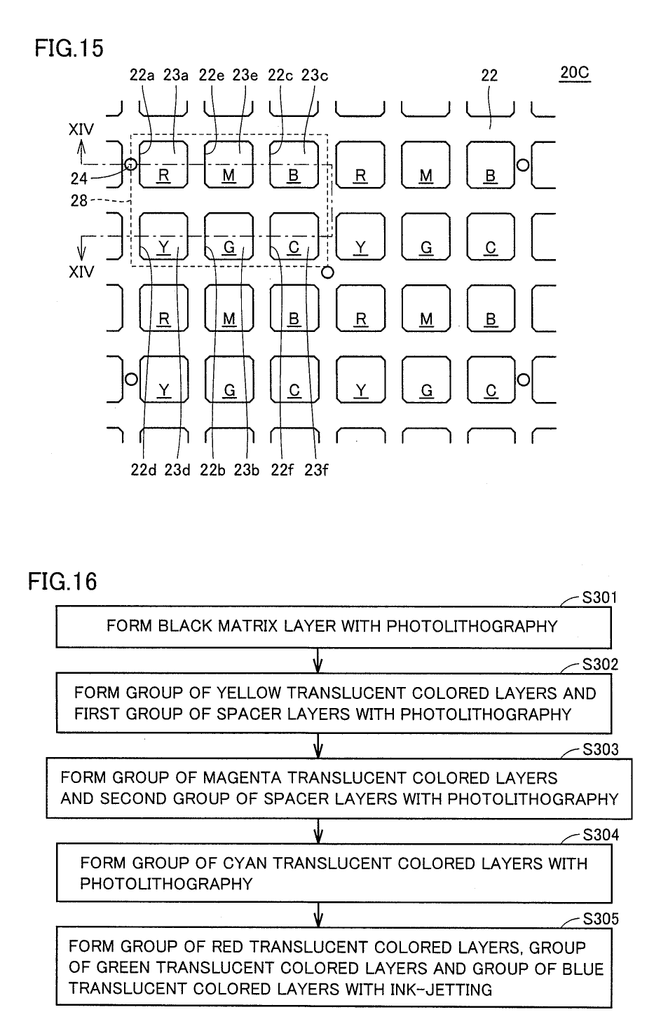

Next, as shown in FIG. 9, a group of red translucent colored layers, a group of green translucent colored layers and a group of blue translucent colored layers are formed on transparent substrate 21 with ink-jetting (step S203). More specifically, as shown in FIG. 11A, a predetermined amount of red ink 23x is dropped onto a portion of transparent substrate 21 where first opening 22a of black matrix layer 22 has been provided, a predetermined amount of green ink 23y is dropped onto a portion of transparent substrate 21 where second opening 22b of black matrix layer 22 has been provided, and a predetermined amount of blue ink 23z is dropped onto a portion of transparent substrate 21 where third opening 22c of black matrix layer 22 has been provided, respectively, with nozzle 41 provided on an ink jet head 40B, and then cured by heating. As a result, red colored layer 23a is formed in first opening 22a of black matrix layer 22, green colored layer 23b is formed in second opening 22b of black matrix layer 22, and blue colored layer 23c is formed in third opening 22c of black matrix layer 22, respectively, as shown in FIG. 11B.

Next, as shown in FIG. 9, a group of spacer layers is formed on a predetermined portion of black matrix layer 22 with photolithography (step S204). More specifically, as shown in FIG. 11C, black photosensitive resin liquid is applied with spin coating and dried, for example, across black matrix layer 22, the group of red translucent colored layers, the group of green translucent colored layers, the group of blue translucent colored layers and the group of yellow translucent colored layers, to form black photosensitive resin layer 24p, and black photosensitive resin layer 24p is then exposed to light with a photomask 33B having a predetermined opening shape, followed by development with a predetermined etching solution. As a result, spacer layer 24 is formed on the predetermined portion of black matrix layer 22 as shown in FIG. 11D.

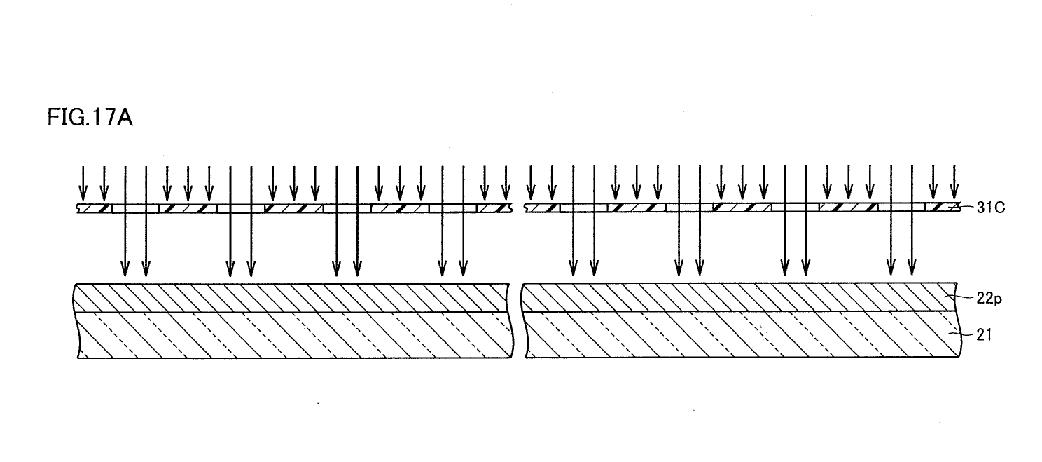

Next, an ITO film is formed with sputtering, for example, to cover black matrix layer 22, the group of red translucent colored layers, the group of green translucent colored layers, the group of blue translucent colored layers, the group of yellow translucent colored layers and the group of spacer layers, to form counter electrode 25, and polyimide resin is further applied with spin coating and dried on counter electrode 25, for example, to form liquid-crystal alignment film 26. As a result, manufacture of CF substrate 20B (color filter) as shown in FIG. 12 is completed.

As described above, in the present embodiment, the black matrix layer is formed with photolithography, the group of yellow translucent colored layers is formed with photolithography, and the group of red translucent colored layers, the group of green translucent colored layers and the group of blue translucent colored layers are formed with ink-jetting. Thus, the black matrix layer can be formed with a higher degree of accuracy with photolithography, and the group of yellow translucent colored layers can be formed with photolithography rather than ink-jetting using yellow ink which is difficult to prepare compared to inks of other colors, further facilitating the formation of the group of yellow translucent colored layers. In addition, the group of red translucent colored layers, the group of green translucent colored layers and the group of blue translucent colored layers can be simultaneously formed with ink-jetting, further facilitating the formation of the group of red translucent colored layers, the group of green translucent colored layers and the group of blue translucent colored layers. Accordingly, the color filter can be manufactured by utilizing the respective advantages of photolithography and ink-jetting.

Furthermore, in the color filter of the present embodiment, the black matrix layer is formed on the border portions between the colored layers, so that the black matrix layer can prevent light incidence on a clearance between the pixels or on a region where a TFT has been formed. Accordingly, the liquid crystal panel including the color filter in the present embodiment is capable of high-quality display.

According to the present embodiment, therefore, a liquid crystal panel capable of high-quality display can be manufactured at low cost by utilizing the respective advantages of photolithography and ink-jetting, allowing manufacture of a high-performance liquid crystal panel at low cost.

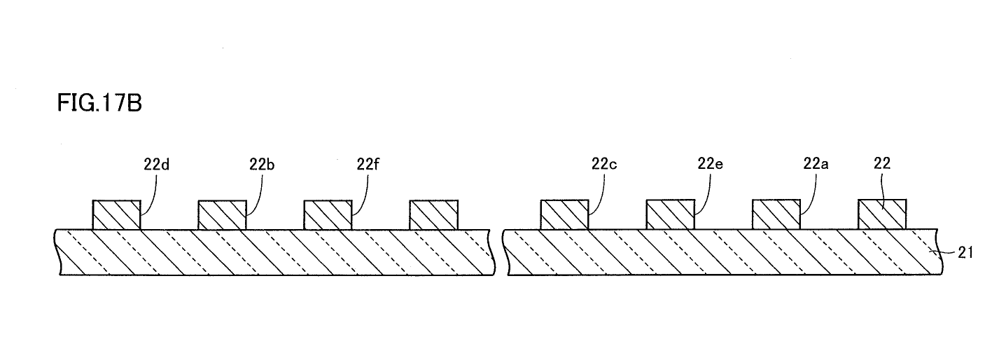

While the above present embodiment has been described by referring to the exemplary color filter including the stripe-shaped colored layers of four colors composed of red colored layer 23a, green colored layer 23b, blue colored layer 23c and yellow colored layer 23d in parallel with one another in each pixel 28, it is not required for these four colored layers to be formed in stripes and in parallel with one another. FIG. 13 is a plan view of an enlarged portion of a color filter according to another example in the present embodiment. As shown in FIG. 13, each of four colored layers 23a, 23b, 23c, 23d described above may be formed in a rectangular shape, and a layout may be employed where these four colored layers 23a, 23b, 23c, 23d are alternately arranged in directions of rows and columns, as a color filter 20W according to another example in the present embodiment.

Further, while the above present embodiment has been described by referring to the exemplary color filter including the colored layers of four colors composed of red colored layer 23a, green colored layer 23b, blue colored layer 23c and yellow colored layer 23d in each pixel 28, a colored layer of another color (e.g., white) may be employed instead of yellow colored layer 23d. In that case, the colored layer of another color still needs to be formed with photolithography.

Furthermore, while only the group of yellow translucent colored layers is formed with photolithography among the group of red translucent colored layers, the group of green translucent colored layers, the group of blue translucent colored layers and the group of yellow translucent colored layers in the above present embodiment, one or two groups of translucent colored layers selected from among the group of red translucent colored layers, the group of translucent colored layers and the group of blue translucent colored layers may also be formed with photolithography.

### Third Embodiment

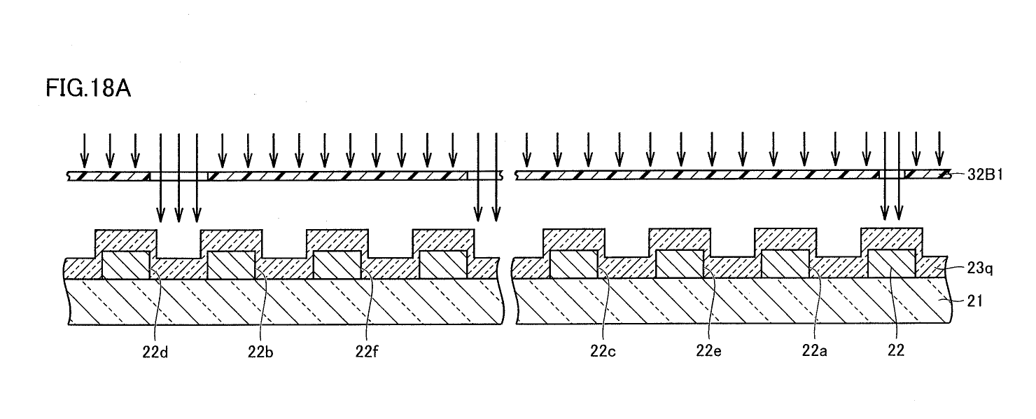

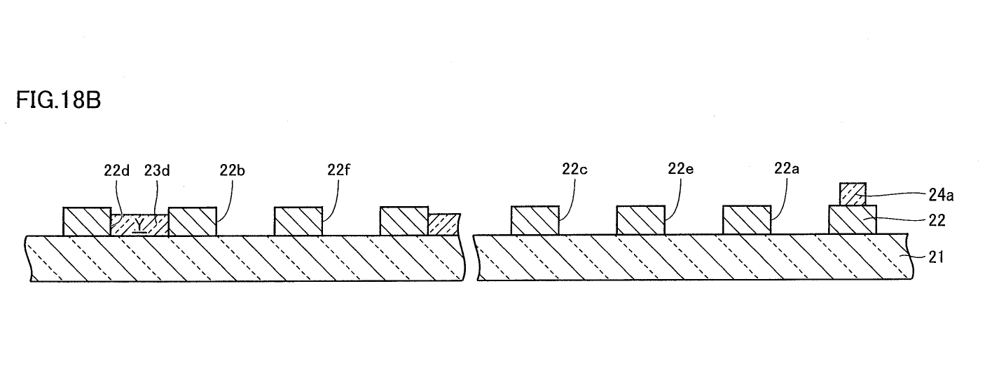

FIG. 14 is a schematic cross-sectional view of a liquid crystal panel including a color filter in a third embodiment of the present invention, and FIG. 15 is a plan view of an enlarged portion of the color filter shown in FIG. 14. FIG. 14 is a schematic cross-sectional view showing the liquid crystal panel cut along the line XIV-XIV shown in FIG. 15. First, referring to FIGS. 14 and 15, the color filter and a structure of the liquid crystal panel including the color filter in the present embodiment will be described in detail. It is noted that the same reference signs are used in the drawings to indicate similar parts to those in the first embodiment described above, and description thereof will not be repeated.

As shown in FIG. 14, the color filter in the present embodiment includes rectangular colored layers of six colors composed of red colored layer 23a, green colored layer 23b, blue colored layer 23c, yellow colored layer 23d, a magenta colored layer 23e and a cyan colored layer 23f alternately arranged in directions of rows and columns in each pixel 28. Thus, the color filter in the present embodiment includes six groups of translucent colored layers composed of a group of red translucent colored layers, a group of green translucent colored layers, a group of blue translucent colored layers, a group of yellow translucent colored layers, a group of magenta translucent colored layers, and a group of cyan translucent colored layers.

As shown in FIGS. 14 and 15, a liquid crystal panel 1C including the color filter in the present embodiment mainly includes TFT substrate 10, a CF substrate 20C, and liquid crystal 18 sealed between TFT substrate 10 and CF substrate 20C. Here, liquid crystal panel 1C including the color filter in the present embodiment is different from liquid crystal panel 1A in the above first embodiment only in structure of the CF substrate.

CF substrate 20C corresponds to a color filter, and mainly includes transparent substrate 21, black matrix layer 22, the six colored layers of different colors composed of red colored layer 23a, green colored layer 23b, blue colored layer 23c, yellow colored layer 23d, magenta colored layer 23e and cyan colored layer 23f provided for each pixel, spacer layer 24, counter electrode 25, and liquid-crystal alignment film 26.

Transparent substrate 21 corresponds to a translucent base member, and is formed of a plate-like glass substrate or plastic substrate, for example. Black matrix layer 22 corresponds to a light-blocking layer, and is provided on the main surface of transparent substrate 21. Six colored layers 23a, 23b, 23c, 23d, 23e, 23f of different colors are provided on the main surface of transparent substrate 21, in portions where black matrix layer 22 is not formed.

Black matrix layer 22 is provided on border portions between respective colored layers 23a, 23b, 23c, 23d, 23e, 23f, and is formed in a lattice pattern by having a plurality of groups of openings. Here, the plurality of groups of openings provided in black matrix layer 22 include six groups of openings composed of a first group of openings, a second group of openings, a third group of openings, a fourth group of openings, a fifth group of openings and a sixth group of openings, which include first opening 22a, second opening 22b, third opening 22c, fourth opening 22d, a fifth opening 22e and a sixth opening 22f provided in each pixel 28, respectively, with the above-mentioned group of red translucent colored layers being provided in the first group of openings, the above-mentioned group of green translucent colored layers being provided in the second group of openings, the above-mentioned group of blue translucent colored layers being provided in the third group of openings, the above-mentioned yellow colored layers being provided in the fourth group of openings, the above-mentioned magenta colored layers being provided in the fifth group of openings, and the above-mentioned cyan colored layers being provided in the sixth group of openings, respectively.

Black matrix layer 22 is formed with photolithography, and is formed of a low-reflection metallic film made of chromium (Cr), molybdenum (Mo) or the like, or a synthetic resin film made of black photosensitive resin containing carbon particles dispersed in photosensitive resin, for example. Red colored layer 23a is formed with ink-jetting using red ink, and is formed of a thermosetting resin film containing dispersed red pigment, for example. Green colored layer 23b is formed with ink-jetting using green ink, and is formed of a thermosetting resin film containing dispersed green pigment, for example. Blue colored layer 23c is formed with ink-jetting using blue ink, and is formed of a thermosetting resin film containing dispersed blue pigment, for example. On the other hand, yellow colored layer 23d is formed with photolithography, and is formed of a photosensitive resin film containing dispersed yellow pigment, for example. Magenta colored layer 23e is formed with photolithography, and is formed of a photosensitive resin film containing dispersed magenta pigment, for example. Cyan colored layer 23f is formed with photolithography, and is formed of a photosensitive resin film containing dispersed magenta pigment, for example.

Spacer layer 24 is provided on a predetermined portion of black matrix layer 22. Spacer layer 24 is to form a predetermined gap between TFT substrate 10 and CF substrate 20B, and a plurality of spacer layers 24 are provided on the surface of the color filter. Spacer layer 24 includes a first spacer layer 24a and a second spacer layer 24b stacked in a thickness direction. First spacer layer 24a is formed with photolithography, and as with yellow colored layer 23d, is formed of a photosensitive resin film containing dispersed yellow pigment, for example. Second spacer layer 24b is formed with photolithography, and as with magenta colored layer 23e, is formed of a photosensitive resin film containing dispersed magenta pigment, for example.

Counter electrode 25 is provided to cover black matrix layer 22, red colored layer 23a, green colored layer 23b, blue colored layer 23c, yellow colored layer 23d, magenta colored layer 23e, cyan colored layer 23f and spacer layer 24 described above. Counter electrode 25 is formed of a transparent electrode film such as an ITO film. Liquid-crystal alignment film 26 is provided on counter electrode 25, and is made of a resin material such as polyimide resin.

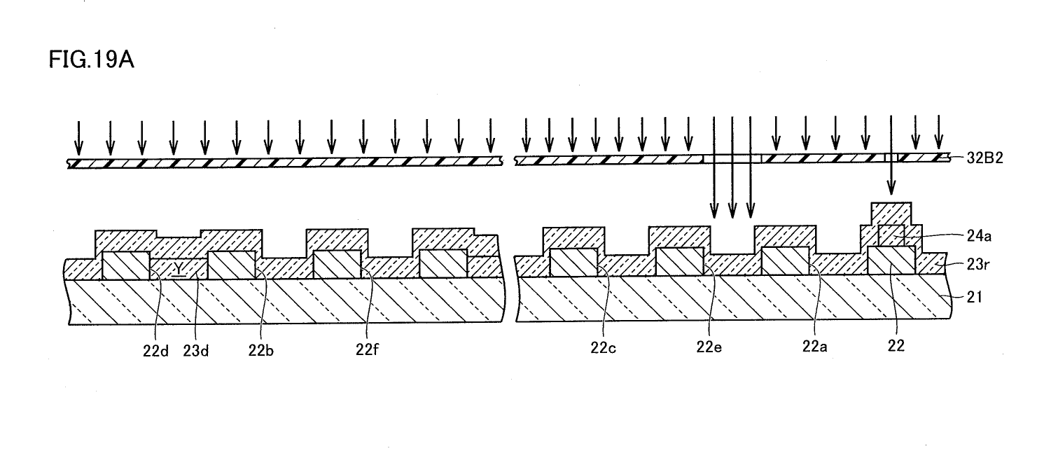

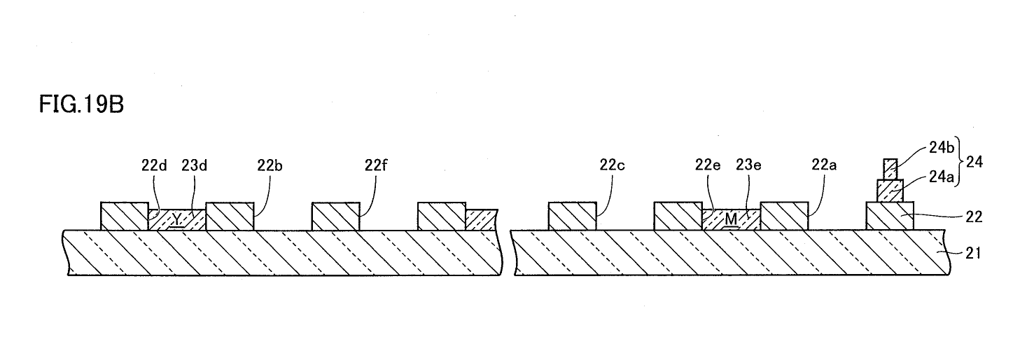

FIG. 16 is a flow diagram for explaining a method of manufacturing the color filter in the present embodiment, and FIGS. 17 to 22 are schematic cross-sectional views during a manufacturing process of manufacturing the color filter in the present embodiment in accordance with the flow. Referring now to FIGS. 16 to 22, the method of manufacturing the color filter in the present embodiment will be described in detail.

As shown in FIG. 16, when manufacturing the color filter in the present embodiment, transparent substrate 21 as a translucent base member is first prepared, and black matrix layer 22 as a light-blocking layer is formed on transparent substrate 21 with photolithography (step S301). More specifically, as shown in FIG. 17A, black photosensitive resin liquid is applied with spin coating and dried, for example, on the main surface of transparent substrate 21, to form black photosensitive resin layer 22p, and black photosensitive resin layer 22p is then exposed to light with a photomask 31C having a predetermined opening shape, followed by development with a predetermined etching solution. As a result, black matrix layer 22 having first opening 22a, second opening 22b, third opening 22c, fourth opening 22d, fifth opening 22e and sixth opening 22f is formed on transparent substrate 21 as shown in FIG. 17B.

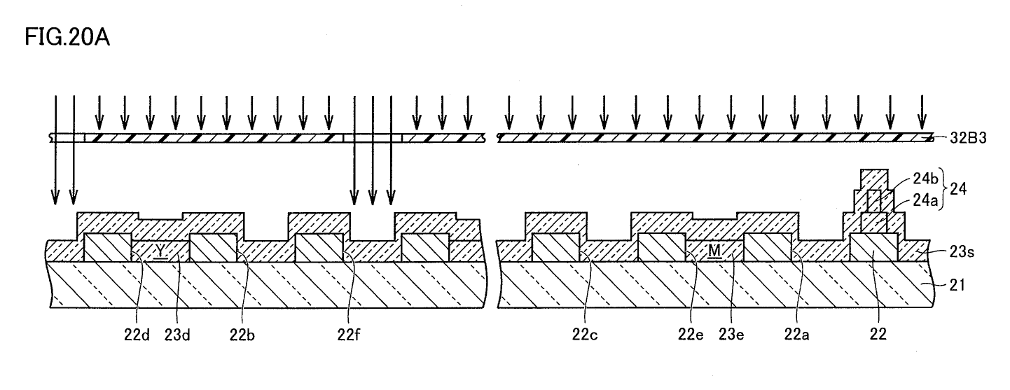

Next, as shown in FIG. 16, a group of yellow translucent colored layers and a first group of spacer layers are formed on transparent substrate 21 with photolithography (step S302). More specifically, as shown in FIG. 18A, yellow photosensitive resin liquid is applied with spin coating and dried, for example, across the main surface of transparent substrate 21 having black matrix layer 22 formed thereon, to form yellow photosensitive resin layer 23q, and yellow photosensitive resin layer 23q is then exposed to light with a photomask 32B1 having a predetermined opening shape, followed by development with a predetermined etching solution. As a result, yellow colored layer 23d is formed in fourth opening 22d of black matrix layer 22, and first spacer layer 24a is formed on a predetermined portion of black matrix layer 22, respectively, as shown in FIG. 18B.

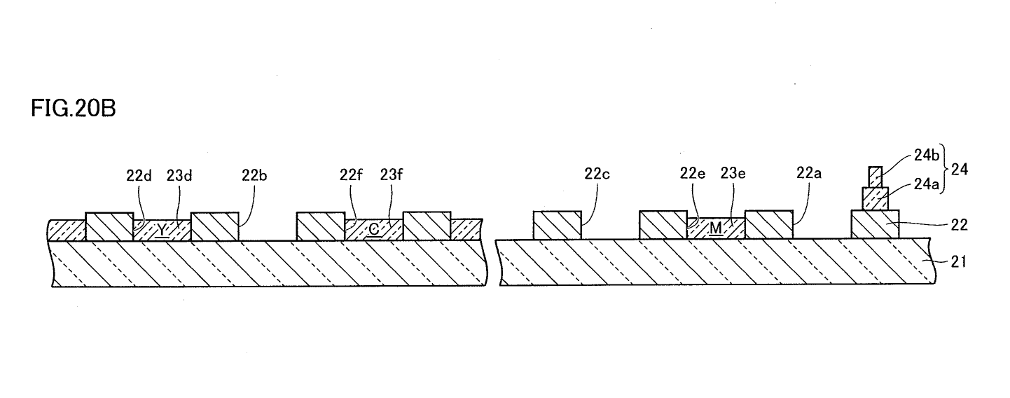

Next, as shown in FIG. 16, a group of magenta translucent colored layers and a second group of spacer layers are formed on transparent substrate 21 with photolithography (step S303). More specifically, as shown in FIG. 19A, magenta photosensitive resin liquid is applied with spin coating and dried, for example, across the main surface of transparent substrate 21 having black matrix layer 22 and yellow colored layer 23d formed thereon, to form a magenta photosensitive resin layer 23r, and magenta photosensitive resin layer 23r is then exposed to light with a photomask 32B2 having a predetermined opening shape, followed by development with a predetermined etching solution. As a result, magenta colored layer 23e is formed in fifth opening 22e of black matrix layer 22, and second spacer layer 24b is formed on first spacer layer 24a, respectively, as shown in FIG. 19B.

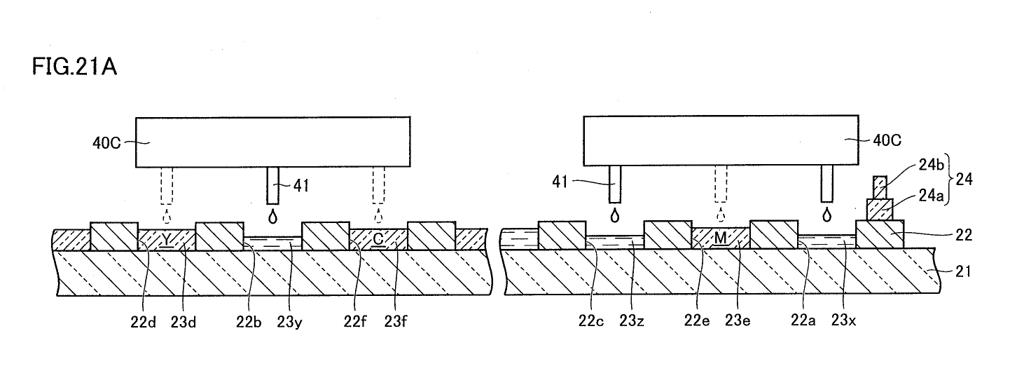

Next, as shown in FIG. 16, a group of cyan translucent colored layers is formed on transparent substrate 21 with photolithography (step S304). More specifically, as shown in FIG. 20A, cyan photosensitive resin liquid is applied with spin coating and dried, for example, across the main surface of transparent substrate 21 having black matrix layer 22, yellow colored layer 23d and magenta colored layer 23e formed thereon, to form a cyan photosensitive resin layer 23s, and cyan photosensitive resin layer 23s is then exposed to light with a photomask 32B3 having a predetermined opening shape, followed by development with a predetermined etching solution. As a result, cyan colored layer 23f is formed in sixth opening 22f of black matrix layer 22 as shown in FIG. 20B.

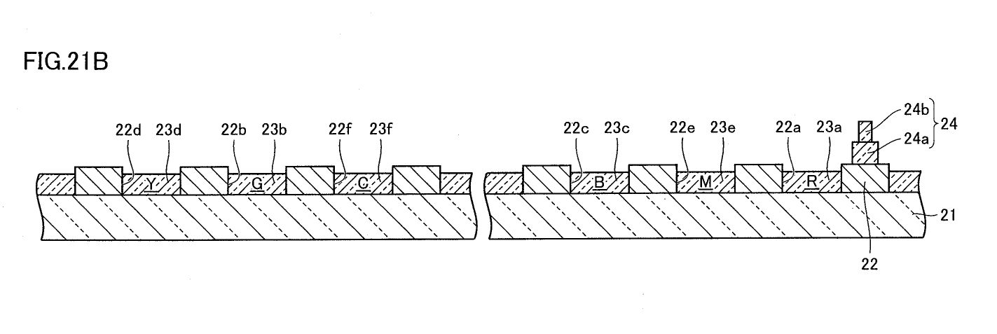

Next, as shown in FIG. 16, a group of red translucent colored layers, a group of green translucent colored layers and a group of blue translucent colored layers are formed on transparent substrate 21 with ink-jetting (step S305). More specifically, as shown in FIG. 21A, a predetermined amount of red ink 22x is dropped onto a portion of transparent substrate 21 where first opening 22a of black matrix layer 22 has been provided, a predetermined amount of green ink 22y is dropped onto a portion of transparent substrate 21 where second opening 22b of black matrix layer 22 has been provided, and a predetermined amount of blue ink 22z is dropped onto a portion of transparent substrate 21 where third opening 22d of black matrix layer 22 has been provided, respectively, with nozzle 41 provided on an ink jet head 40C, and then cured by heating. As a result, red colored layer 23a is formed in first opening 22a of black matrix layer 22, green colored layer 23b is formed in second opening 22b of black matrix layer 22, and blue colored layer 23c is formed in third opening 22c of black matrix layer 22, respectively, as shown in FIG. 21B.

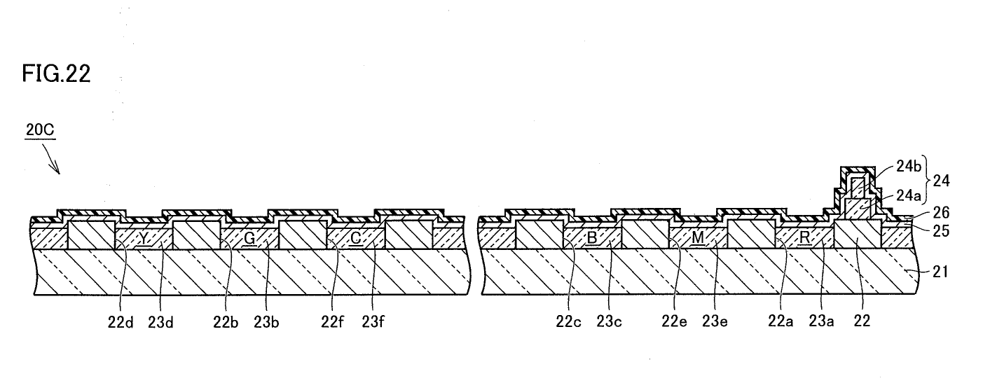

Next, an ITO film is formed with sputtering, for example, to cover black matrix layer 22, the group of red translucent colored layers, the group of green translucent colored layers, the group of blue translucent colored layers, the group of yellow translucent colored layers, the group of magenta translucent colored layers, the group of cyan translucent colored layers and the group of spacer layers, to form counter electrode 25, and polyimide resin is further applied with spin coating and dried on counter electrode 25, for example, to form liquid-crystal alignment film 26. As a result, manufacture of CF substrate 20C (color filter) as shown in FIG. 22 is completed.

As described above, in the present embodiment, the black matrix layer is formed with photolithography, the group of yellow translucent colored layers, the group of magenta translucent colored layers and the group of cyan translucent colored layers are formed with photolithography, and the group of red translucent colored layers, the group of green translucent colored layers and the group of blue translucent colored layers are formed with ink-jetting. Thus, the black matrix layer can be formed with a higher degree of accuracy with photolithography, and the group of yellow translucent colored layers, the group of magenta translucent colored layers and the group of cyan translucent colored layers can be formed with photolithography rather than ink-jetting using yellow ink, magenta ink and cyan ink which are difficult to prepare compared to inks of other colors, further facilitating the formation of the group of yellow translucent colored layers, the group of magenta translucent colored layers and the group of cyan translucent colored layers. In addition, the group of red translucent colored layers, the group of green translucent colored layers and the group of blue translucent colored layers can be simultaneously formed with ink-jetting, further facilitating the formation of the group of red translucent colored layers, the group of green translucent colored layers and the group of blue translucent colored layers. Accordingly, the color filter can be manufactured by utilizing the respective advantages of photolithography and ink-jetting.

Furthermore, in the color filter of the present embodiment, the black matrix layer is formed on the border portions between the colored layers, so that the black matrix layer can prevent light incidence on a clearance between the pixels or on a region where a TFT has been formed. Accordingly, the liquid crystal panel including the color filter in the present embodiment is capable of high-quality display.

According to the present embodiment, therefore, a liquid crystal panel capable of high-quality display can be manufactured at low cost by utilizing the respective advantages of photolithography and ink-jetting, allowing manufacture of a high-performance liquid crystal panel at low cost.

While the above present embodiment has been described by referring to the exemplary color filter including the rectangular colored layers of six colors composed of red colored layer 23a, green colored layer 23b, blue colored layer 23c, yellow colored layer 23d, magenta colored layer 23e and cyan colored layer 23f alternately arranged in directions of rows and columns in each pixel 28, it is not required for these six colored layers to be formed in a rectangular shape and alternately in directions of rows and columns. For example, a layout may be employed where above-described six colored layers 23a, 23b, 23c, 23d, 23e, 23f are formed in stripes and in parallel with one another.

Moreover, while the above present embodiment has been described by referring to the exemplary color filter including the groups of translucent colored layers of six colors composed of the group of red translucent colored layers, the group of green translucent colored layers, the group of blue translucent colored layers, the group of yellow translucent colored layers, the group of magenta translucent colored layers and the group of cyan translucent colored layers, any combination of colors of these groups of translucent colored layers may be employed, and the number of groups of translucent colored layers to be formed is not limited to six. In any case, so long as a color filter includes a plurality of groups of translucent colored layers that are partially formed with photolithography and partially formed with ink-jetting, the above-described effect can be obtained.

The second and third embodiments have been described above by referring to examples where three groups of translucent colored layers are formed with ink-jetting, and the remaining one or three groups of translucent colored layers are formed with photolithography. By forming three groups of translucent colored layers selected from among four or more groups of translucent colored layers of different colors with ink-jetting, and forming the remaining group of translucent colored layers with photolithography in this manner, existing production equipment can be efficiently utilized. This is because existing production equipment often employs a so-called three-color ink jet device which can reproduce three colors of red, green and blue, and thus efficient utilization of such ink jet device cannot be achieved if groups of translucent colored layers of two or less or four or more colors are formed with ink-jetting. According to the above second and third embodiments, therefore, existing ink jet devices can be utilized most efficiently without change, thereby suppressing increase in manufacturing costs.

Furthermore, while each of the first to third embodiments has been described by referring to an example where the groups of translucent colored layers are formed initially with photolithography and then with ink-jetting, the methods can be used in reverse order, or used alternately.

It should be understood that the embodiments disclosed herein are illustrative and non-restrictive in every respect. The technical scope of the present invention is defined by the terms of the claims, and is intended to include any modifications within the scope and meaning equivalent to the terms of the claims.

### REFERENCE SIGNS LIST

1A, 1B, 1C liquid crystal panel; 10 TFT substrate; 11 transparent substrate; 12 TFT circuit layer; 13 insulating layer; 14 pixel electrode; 15 liquid-crystal alignment film; 18 liquid crystal; 20A, 20B, 20C CF substrate; 21 transparent substrate; 22 black matrix layer; 22a first opening; 22b second opening; 22c third opening; 22d fourth opening; 22e fifth opening; 22f sixth opening; 22p black photosensitive resin layer; 23a red colored layer; 23b green colored layer; 23c blue colored layer; 23d yellow colored layer; 23e magenta colored layer; 23f cyan colored layer; 23p blue photosensitive resin layer; 23q yellow photosensitive resin layer; 23r magenta photosensitive resin layer; 23s cyan photosensitive resin layer; 23x red ink; 23y green ink; 23z blue ink; 24 spacer layer; 24a first spacer layer; 24b second spacer layer; 24p black photosensitive resin layer; 25 counter electrode; 26 liquid-crystal alignment film; 28 pixel; 31A, 31B, 31B1, 31B2, 31B3, 31C photomask; 40A, 40B, 40C ink jet head, 41 nozzle.

1. A method of manufacturing a color filter including a plurality of groups of translucent colored layers of different colors on a translucent base member, comprising the steps of:
forming a light-blocking layer including a plurality of groups of openings on said base member with photolithography;
forming one group of translucent colored layers selected from among said plurality of groups of translucent colored layers in one group of openings selected from among said plurality of groups of openings with photolithography; and
forming another group of translucent colored layers selected from among said plurality of groups of translucent colored layers in another group of openings selected from among said plurality of groups of openings with ink-jetting.

2. The method of manufacturing a color filter according to claim 1, wherein
said step of forming said one group of translucent colored layers with photolithography is performed before said step of forming said another group of translucent colored layers with ink-jetting.

3. The method of manufacturing a color filter according to claim 1, wherein
said step of forming said another group of translucent colored layers with ink jetting is performed before said step of forming said one group of translucent colored layers with photolithography.

4. The method of manufacturing a color filter according to claim 1, wherein
in said step of forming said one group of translucent colored layers with photolithography, a group of spacer layers positioned to project on a predetermined portion of said light-blocking layer is formed simultaneously with said one group of translucent colored layers.

5. The method of manufacturing a color filter according to claim 1, wherein
said plurality of groups of translucent colored layers include at least four or more groups of translucent colored layers of different colors, and
three groups of translucent colored layers selected from among these four or more groups of translucent colored layers are formed with ink-jetting, and a remaining group of translucent colored layers is formed with photolithography.

6. The method of manufacturing a color filter according to claim 1, wherein
said plurality of groups of translucent colored layers include three groups of translucent colored layers composed of a group of red translucent colored layers, a group of green translucent colored layers and a group of blue translucent colored layers, and
at least one group of translucent colored layers selected from among these three groups of translucent colored layers is formed with photolithography, and a remaining group of translucent colored layers is formed with ink-jetting.

7. The method of manufacturing a color filter according to claim 1, wherein
said plurality of groups of translucent colored layers include four groups of translucent colored layers composed of a group of red translucent colored layers a group of green translucent colored layers, a group of blue translucent colored layers and a group of yellow translucent colored layers, and
at least one group of translucent colored layers selected from among these four groups of translucent colored layers is formed with photolithography, and a remaining group of translucent colored layers is formed with ink-jetting.

8. The method of manufacturing a color filter according to claim 1, wherein
said plurality of groups of translucent colored layers include four groups of translucent colored layers composed of a group of red translucent colored layers, a group of green translucent colored layers, a group of blue translucent colored layers and a group of white translucent colored layers, and
at least one group of translucent colored layers selected from among these four groups of translucent colored layers is formed with photolithography, and a remaining group of translucent colored layers is formed with ink-jetting.

9. The method of manufacturing a color filter according to claim 1, wherein
said plurality of groups of translucent colored layers include six groups of translucent colored layers composed of a group of red translucent colored layers, a group of green translucent colored layers, a group of blue translucent colored layers, a group of yellow translucent colored layers, a group of magenta translucent colored layers and a group of cyan translucent colored layers, and
at least one group of translucent colored layers selected from among these six groups of translucent colored layers is formed with photolithography, and a remaining group of translucent colored layers is formed with ink-jetting.

10. The method of manufacturing a color filter according to claim 1, wherein
said light-blocking layer is a black matrix layer formed of a low-reflection metallic film or a synthetic resin film.

11. A color filter comprising:
a translucent base member;
a light-blocking layer including a plurality of groups of openings provided on said base member; and
a plurality of groups of translucent colored layers of different colors provided on said base member,
one group of translucent colored layers selected from among said plurality of groups of translucent colored layers being formed in one group of openings selected from among said plurality of groups of openings with photolithography, and
another group of translucent colored layers selected from among said plurality of groups of translucent colored layers being formed in another group of openings selected from among said plurality of groups of openings with ink-jetting.

12. The color filter according to claim 11, further comprising a group of spacer layers positioned to project on a predetermined portion of said light-blocking layer, wherein
said one group of translucent colored layers and said group of spacer layers are simultaneously formed in one step.

13. The color filter according to claim 11, wherein
said plurality of groups of translucent colored layers include three groups of translucent colored layers composed of a group of red translucent colored layers, a group of green translucent colored layers and a group of blue translucent colored layers.

14. The color filter according to claim 11, wherein
said plurality of groups of translucent colored layers include four groups of translucent colored layers composed of a group of red translucent colored layers, a group of green translucent colored layers, a group of blue translucent colored layers and a group of yellow translucent colored layers.

15. The color filter according to claim 11, wherein
said plurality of groups of translucent colored layers include four groups of translucent colored layers composed of a group of red translucent colored layers, a group of green translucent colored layers, a group of blue translucent colored layers and a group of white translucent colored layers.

16. The color filter according to claim 11, wherein
said plurality of groups of translucent colored layers include six groups of translucent colored layers composed of a group of red translucent colored layers, a group of green translucent colored layers, a group of blue translucent colored layers, a group of yellow translucent colored layers, a group of magenta translucent colored layers and a group of cyan translucent colored layers.

17. The color filter according to claim 11, wherein
said light-blocking layer is a black matrix layer formed of a low-reflection metallic film or a synthetic resin film.
